(19) United States
(12) Patent Application Publication
(10) Pub. No.: US 2023/0207151 A1
(43) Pub. Date: Jun. 29, 2023

(54) CONDUCTIVE FILM, CONDUCTIVE PASTE, AND PRODUCTION METHOD THEREOF

(71) Applicant: LG ELECTRONICS INC., Seoul (KR)

(72) Inventors: Soongil KIM, Seoul (KR); Hongjung KIM, Seoul (KR); Jongdeok KIM, Seoul (KR)

(73) Assignee: LG ELECTRONICS INC., Seoul (KR)

(21) Appl. No.: 17/927,350

(22) PCT Filed: May 26, 2020
(86) PCT No.: PCT/KR2020/006782

§ 371 Date: Nov. 22, 2022

(51) Int. Cl. H01B 1/22; H01B 13/00; H01B 5/14

(52) U.S. Cl. CPC H01B 1/22; H01B 5/14; H01B 13/0016

(57) ABSTRACT

The present invention comprises the steps of: applying, on a substrate, a conductive paste including metal particles that are dispersed in an organic material and have a first particle diameter, and a magnetic heating element that has a second particle diameter; and selectively sintering the applied conductive paste by induction heating to form a conductive film, wherein the magnetic heating element may be contained in an amount of 10-50 wt% with respect to the metal particles. Therefore, a conductive adhesive layer can be selectively formed by performing the sintering through induction heating. In addition, by adding a small amount of the magnetic heating element to conductive metal powder having a low melting point, low-temperature bonding and electric conductivity can be simultaneously attained.

### BACKGROUND

### FIELD OF THE INVENTION

The present invention relates to a conductive film and a conductive paste for forming the conductive film, and more particularly, to a method of forming a conductive paste by mixing a heating element having a high magnetic susceptibility and conductive metal particles, and printing the same on a substrate to form a conductive film.

### RELATED ART

Currently, device bonding using a conductive adhesive of silver (Ag) paste is widely used as a bonding technology. As bonding using such a bonding paste, there are a pressurized method and a non-pressurized method.

In the case of the pressurized method, the bonding strength is very high by placing a desired chip over a silver paste and simultaneously performing sintering and bonding while applying heat and pressure at the same time, but there is a risk of deformation due to pressure applied to the device chip and the entire module.

In the case of the non-pressurized method, a method that promotes sintering by forming the size of silver particles very small and ensures the sintering speed by making it difficult to disperse has been proposed. However, since this method has weak bonding strength and requires a relatively high temperature, damage to an electronic device due to heat is an issue.

In this regard, as the related art, in Korean Patent Application No. 10-2015-0185221, metal particles having a magnetic susceptibility are coated with a material having conductivity. Such coated metal particles are dispersed in a resin or the like to form a conductive film, which may function as an adhesive layer.

Specifically, when induction heating is performed over the conductive film, the metal particles inside are magnetized to generate heat, and by heating a coating layer by the heat, the coating layer may be melted and bonding may be performed.

However, in this related art, even when sintering through induction heating is completed, an oxide layer is present on the surface of the coating layer and the sintering density is lowered, so that the sheet resistance is very high and electrical conductivity is remarkably reduced.

In addition, even when the process of coating each metal particle with a different metal layer is performed, it is difficult to smoothly form the coating layer, so there is an issue in that uniform electrical conductivity and contact force may not be expected.

### Related Art Document

Korean Patent Application No. 10-2015-0185221 (publication date: Jul. 4, 2017)

### SUMMARY

A first aspect of the present invention is to provide a conductive paste capable of forming a conductive adhesive layer by sintering through induction heating, and a method of producing the same.

A second aspect of the present invention is to provide a conductive film capable of simultaneously attaining low-temperature bonding and electrical conductivity by adding a small amount of a magnetic heating element to a conductive metal powder having a low melting point, and a conductive paste for producing the same.

A third aspect of the present invention is to provide a conductive film capable of high-speed bonding since induction heating is performed in a short time to selectively heat only a portion where the conductive film is formed.

An embodiment of the present invention provides a conductive paste including: an organic material including an organic solvent and a dispersant; metal particles dispersed in the organic material and having a first particle diameter; and a magnetic heating element dispersed in the organic material and having a second particle diameter, wherein the magnetic heating element is contained in an amount of 10 to 50 wt% with respect to the metal particles.

The second particle diameter of the magnetic heating element may be the same as or smaller than the first particle diameter of the metal particles.

The magnetic heating element may be mixed in an amount of 10 to 20 wt% with respect to the metal particles.

The magnetic heating element may be a metal oxide-based magnetic heating element.

The magnetic heating element may be a Fe₃O₄ magnetic heating element.

The metal particles may be at least one of Ag, Ag, Al, Pt, Sn, Cu, Zn, Pd, and Ni.

The first particle diameter may be 10 nm to 100 um.

The first particle diameter may be 10 nm to 50 um.

The second particle diameter may be 10 nm to 10 um.

The dispersant or organic solvent of the organic material may have 30 or less carbon atoms.

The organic material may further include a binder and a catalyst.

The thickness of the conductive paste may be 0.001 mm to 0.5 mm.

An embodiment of the present invention provides a method of producing a conductive paste, wherein the method includes: mixing and dispersing an organic material and metal particles having a first particle diameter; dispersing a magnetic heating element having a second particle diameter of 10 to 50 wt% with respect to the metal particles in the organic material in which the metal particles are dispersed; and post-processing and subdividing the organic material in which the metal particles and the magnetic heating element are mixed.

The second particle diameter of the magnetic heating element may be the same as or smaller than the first particle diameter of the metal particles.

The magnetic heating element may be mixed in an amount of 10 to 20 wt% with respect to the metal particles.

An embodiment of the present invention provides a method of producing a conductive film, wherein the method includes: applying, on a substrate, a conductive paste including metal particles that are dispersed in an organic material and have a first particle diameter, and a magnetic heating element that has a second particle diameter; and selectively sintering the applied conductive paste by induction heating to form a conductive film, wherein the magnetic heating element may be contained in an amount of 10-50 wt% with respect to the metal particles.

In the induction heating, the conductive paste may be sintered through a magnetic field generated by a high frequency ranging from 1 kHz to 40 MHz.

In the induction heating, the temperature may be raised to 200° C. or higher within 20 seconds.

In the applying, on the substrate, of the conductive paste, the conductive paste may be applied over the substrate by a roll-to-roll method or a printing method.

The method may further include disposing an adhesive object over the conductive paste after applying the conductive paste on the substrate.

Thereby, an embodiment of the present invention can selectively form a conductive adhesive layer by performing the sintering through induction heating.

In addition, by adding a small amount of the magnetic heating element to conductive metal powder having a low melting point, low-temperature bonding and electric conductivity can be simultaneously attained.

High-speed bonding is possible because induction heating is performed in a short time and only the portion where the conductive film is formed is selectively heated. In addition, the sintering density of the conductive film can be improved because the magnetic heating element dispersed in the conductive film is simultaneously heated during induction heating to simultaneously remove the organic materials present therein.

In addition, since the size of the magnetic heating element is similarly small to the size of the metal particles, it is possible to lower raw material prices.

### BRIEF DESCRIPTION OF THE DRAWINGS

FIG. 1 illustrates a conductive film substrate according to an embodiment of the present invention.

FIG. 2 is a flowchart illustrating a method of producing a conductive paste for forming the conductive film of FIG. 1.

FIGS. 3A and 3B are configuration diagrams for explanation of FIG. 2.

FIG. 4 is a flowchart illustrating a method of forming the conductive film substrate of FIG. 1.

FIGS. 5A to 5D are process diagrams illustrating the process of FIG. 4.

FIG. 6 is a graph illustrating the relationship between electrical conductivity with respect to the content of a magnetic heating element according to the device and a graph illustrating the relationship between electrical conductivity and bonding strength.

FIG. 7 is a graph illustrating the induction heating temperature according to time for each material.

FIGS. 8A and 8B show a surface photograph and a tomographic photograph of a conductive film produced according to an embodiment of the present invention, respectively.

### DESCRIPTION OF EXEMPLARY EMBODIMENTS

Expressions referring to directions such as “front(F)/rear(R)/left(Le)/right(Ri)/up (U)/down (D)” mentioned below are defined as indicated in the drawings. However, the expressions are only to explain the present invention so that the present invention can be clearly understood, and the directions may be differently defined depending on a criterion.

Use of terms “first and second” in front of components mentioned below is only to avoid confusion of the referred component, and is independent of an order, importance, or master/slave relationship between the components. For example, an embodiment including only a second component without a first component can be implemented.

In the drawings, a thickness or a size of each component is exaggerated, omitted, or schematically illustrated for convenience and clarity of the explanation. The size and area of each component do not entirely reflect the actual size or area.

Moreover, an angle and a direction mentioned in describing a structure of the present invention are based on those described in the drawings. In description of a structure in the specification, if a reference point and a positional relationship with respect to the angle are not explicitly mentioned, reference is made to the related drawings.

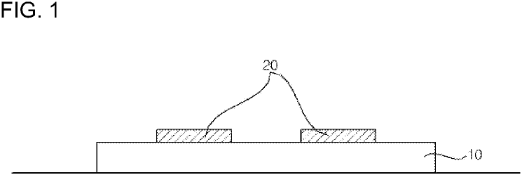

Hereinafter, with reference to FIGS. 1 to 3, a conductive film substrate and a method of producing a conductive paste therefor of an embodiment of the present invention will be described.

FIG. 1 illustrates a conductive film 20 substrate 10 according to an embodiment of the present invention.

Referring to FIG. 1, the conductive film 20 is formed by printing a conductive paste and then sintering the same by induction heating. In this connection, the conductive film 20 is formed including metal particles 21 and a magnetic heating element 23 dispersed in an organic material 22.

The conductive film 20 is formed by selectively sintering only the conductive film 20 by induction heating after a conductive paste is applied or printed on an upper portion of the substrate 10. Herein, in the induction heating, when the magnetic heating element 23 included in the conductive paste receives magnetic force by induction heating from the outside, heat is generated on the surface of the magnetic heating element 23 and sintering of the metal particles 21 is performed.

The organic material 22 included in the conductive film 20 may include a dispersant or an organic solvent.

The dispersant is designed to prevent the metal particles 21 from being aggregated or agglomerated together, and the organic solvent is designed to mix all the components and is removed during a sintering process. When the molecular weight of the organic material 22 is too large, the thermal decomposition temperature is high so that high temperature heat treatment or long-time heat treatment is required. When the molecular weight of the organic material 22 is too small, it is easily dried in the air and it is difficult to secure flow characteristics, so that an appropriate organic material 22 suitable for process conditions is selected.

In addition, the organic material 22 may further include a binder, a catalyst, and the like.

For all organic materials 22, it is preferable to use those having a low carbon number, preferably 30 or less. When the number of carbon atoms is too large, the boiling point of the organic material 22 increases, so that during sintering (or bonding), the dispersant remains inside the paste. This may cause issues with the sintering density (or bonding strength) and reliability.

The magnetic heating element 23 mixed with the metal particles 21 and dispersed may include a metal-based, alloy-based, oxide-based, nitride-based material containing at least one of Fe, Ni, Co, and Sm, and is composed of a material having magnetic properties.

The magnetic heating element 23 sinters the metal particles 21 present in the conductive paste by induction heating. The particle diameter of the magnetic heating element 23 is a size that may be included in the thickness of the paste, and is selected in consideration of the heating characteristics according to the induction heating frequency.

In the case of the magnetic heating element 23, the maximum amount of heat may be realized at the optimal particle diameter (single domain). Specifically, the powder particle diameter of the magnetic heating element 23 may be 10 nm to 100 um, preferably 10 nm to 50 um, and more preferably 10 nm to 10 um.

The powder size of the magnetic heating element 23 may be similar to or smaller than the size of the metal particles 21. The type of the magnetic heating element 23 may include a metallic, metal-based, ceramic-based, or oxide-based one as a material capable of generating heat by an alternating magnetic field generated in high-frequency induction heating.

Examples of the metallic heating element 23 may include Fe, Co, Ni Al, Cu, Mo, Ag, Au, Mg, or a metal or alloy containing at least one thereof. Examples of the metal-based magnetic heating element 23 may include Fe, Co, Ni, FexNiy, MnBi, SmCo₅, Sm₂Co₁₇, SmFe₁₁Ti or at least one thereof. Examples of the ceramic-based magnetic heating element 23 may include NdFe₁₄B, NdFe₁₄B, NdFe₁₄C, Sm₂Fe₁₇N₃, Sm₂Fe₁₇Cx, and SmFe₇N. The oxide-based magnetic heating element 23 is a ferrite such as FesO₄, and may be a ferrite represented by XFeyOz (which may include one or two or more of X: Fe, Co, Ni, Mn, Mg, Cu, Zn, Cr, Ti, Mn, and the like).

The shape of the magnetic heating element 23 may be applied in various forms such as spherical, plate-shaped, needle-shaped, and the like. The magnetic heating element 23 may be 0.01 to 50 wt% with respect to the metal particles 21, preferably 1 to 40 wt%, more preferably 5 to 30 wt%, and most preferably 10 to 20 wt%.

When the content of the magnetic heating element 23 is high, the sintering density (bonding strength) is low, and when the content of the magnetic heating element 23 is low, it is difficult to shorten the sintering (bonding) process time. However, by reducing the size of the metal particles 21 and reducing the content of the magnetic heating element to a small amount, the optimum condition may be satisfied.

The metal particles 21 impart electrical conductivity of the conductive film 20 as a main material configuring the conductive paste. Since the metal particles 21 are present in a particulate form, sintering is required at a specific temperature (metal melting temperature) or higher to have electrical conductivity, and a low melting temperature is required for selective melting, in other words, in order not to affect another device.

To this end, the metal particles 21 of the present embodiment may secure electrical conductivity by miniaturizing a particle size to a nano size. For example, the metal particles 21 may include at least one of Ag, Ag, Al, Pt, Sn, Cu, Zn, Pd, and Ni.

The metal particles 21 may have an average particle diameter of 10 nm to 100 um, preferably 10 nm to 50 um, more preferably 10 nm to 10 um, and most preferably 10 nm to 5 um.

When the particle diameter is smaller than the above range, the content of the organic dispersant present on the surface of the metal particles 21 is rapidly increased, and the residual carbon during sintering increases, so that the sintering density and electrical conductivity may be lowered. When the size of the particles is too large, the sintering temperature to secure electrical conductivity increases, which may cause thermal damage to a product.

The shape of the metal particles 21 may be implemented in various ways, and various shapes of the metal particles 21 may be mixed and used according to the field of application, such as a spherical shape, a cylindrical shape, a needle shape, a plate shape, and a wire shape.

The aspect ratio (ratio of width to height) of the metal particles 21 may be variably changed according to the sintering temperature and the initial packing density.

As such, the conductive paste used to form the conductive film 20 has a wide thickness of 0.0001 mm (0.1 um or 100 nm) to 50 mm (5 cm), preferably 0.0005 mm (0.5 um or 500 nm) to 10 mm (1 cm), and more preferably 0.001 mm (1 um or 1000 nm) to 0.5 mm (500 um). When the thickness of the conductive paste is too thick, it takes a long time to remove the organic material 22 present in the paste, so it may be adjusted within the above thickness.

The conductive film 20 is formed by applying or printing the conductive paste and sintering the same through induction heating.

In this connection, the substrate 10 may be a substrate 10 of various materials, and even when the substrate 10 is a flexible substrate 10, the substrate 10 may not be deformed by low-temperature sintering by selective induction heating.

The conductive paste for forming the conductive film 20 is formed by mixing the metal particles 21 and the magnetic heating element 23 dispersed in the organic material 22 as described above. In addition, it is possible to form the conductive film 20 in which electrical conductivity and device stability are secured by heating and melting the adjacent metal particles 21 by induction heating of the magnetic heating element 23. In addition, when sintering by induction heating proceeds, it is economical because sintering proceeds in a short time while proceeding at a low temperature.

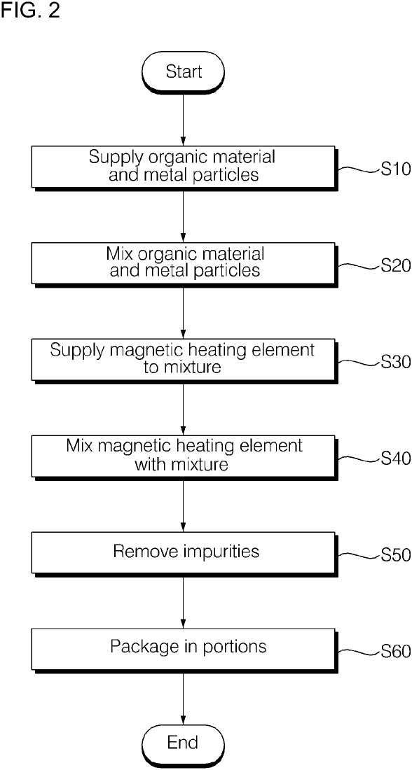

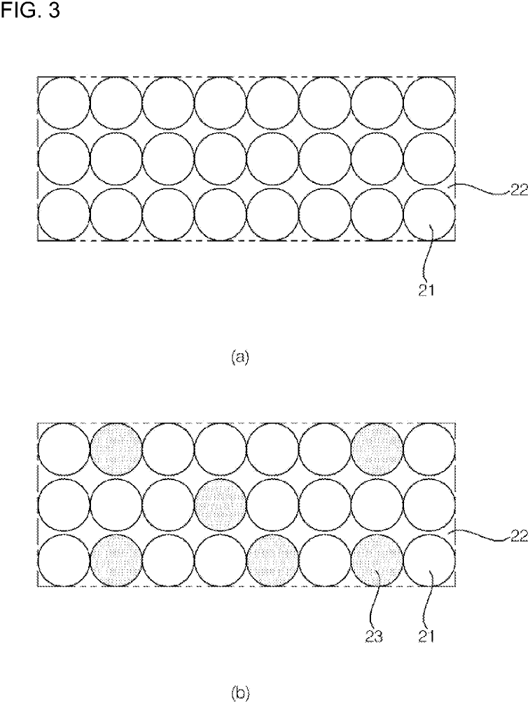

Hereinafter, a method of producing such a conductive paste will be described with reference to FIGS. 2 and 3.

FIG. 2 is a flowchart illustrating a method of producing a conductive paste for forming the conductive film 20 of FIG. 1, and FIGS. 3A and 3B are configuration diagrams for explanation of FIG. 2.

Referring to FIG. 2, the organic material 22 and the metal particles 21 are supplied (S10).

The organic material 22 may include the aforementioned organic solvent and dispersant binder.

In this connection, the organic solvent may be formed of a mixture of ethylene carbonate (EC) and Texanol Ester Alcohol (texanol). The dispersant may use a mixture of one or more selected from carboxylic acids, amines, and alcohols. These dispersants may organically coat the surface of the metal particles 21 to improve dispersibility in organic solvents.

In addition, it may further include a binder and a reducing agent, and the dispersant prevents the metal particles 21 from being aggregated or agglomerated together. In other words, in producing the paste, it is prevented that the metal particles 21 are attached to each other to form agglomeration. Herein, the dispersant may include at least one of alkylamine, polyamine, carboxylic acid, polycarboxylic acid, carboxylate, polycarboxylate, carboxylic acid amide, polycarboxylic acid amide, alkyl alcohol, polyalcohol, alkyl thiol, poly thiol, and poly ether.

The binder increases strength by imparting elasticity and adhesion to the metal particles 21 when producing the paste, and may preferably be polyvinylpyrrolidone (PVP).

In addition, various additives capable of improving the characteristics of the metal particles 21 and the magnetic heating element 23 may be added.

As described above, the metal particles 21 may include at least one of Ag, Ag, Al, Pt, Sn, Cu, Zn, Pd, and Ni. The metal particles 21 may have an average particle diameter of 10 nm to 100 um, preferably 10 nm to 50 um, more preferably 10 nm to 10 um, and most preferably 10 nm to 5 um.

Next, the organic material 22 and the metal particles 21 are mixed (S20).

In this connection, as a mixing method, chemical solvent mixing or high temperature mechanical mixing may be performed, without being limited thereto.

The materials mixed as such have a form in which the metal particles 21 are smoothly dispersed in the organic material 22 as shown in FIG. 3A.

Next, the magnetic heating element 23 for supplying a secondary raw material is prepared (S30).

As described above, the magnetic heating element 23 is also a material capable of generating heat by an alternating magnetic field generated in high-frequency induction heating, for example, ferrite such as Fe₃O₄ may be provided.

The shape of the magnetic heating element 23 may be applied in various forms such as spherical, plate-shaped, needle-shaped, and the like. The heating element 23 may be 0.01 to 50 wt% with respect to the metal particles 21, preferably 1 to 40 wt%, more preferably 5 to 30 wt%, and most preferably 10 to 20 wt%.

Such a predetermined ratio of the magnetic heating element 23 is mixed in the material of FIG. 3A (S40).

Also in that case, as a mixing method, chemical solvent mixing or high temperature mechanical mixing is applicable.

In this connection, since the metal particles 21 and the magnetic heating element 23 are similar in size and the number thereof is less than that the magnetic heating elements 23, the magnetic heating element 23 may be disposed with a smaller density than the metal particles 21 as shown in FIG. 3B.

Next, filtering is performed (S50). Filtering is performed to remove impurities by performing heat treatment or the like. First, large aggregates may be removed through physical filtering, and impurities may be removed by secondarily performing chemical filtering.

Next, it may be packaged in portions into an appropriate amount to form a conductive paste (S60).

The conductive paste produced in this way may be provided as a solder for conductive adhesion between devices, and may be applied to small electronic devices such as light emitting devices and solar cells.

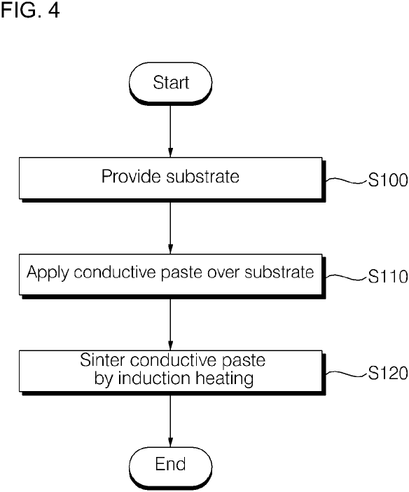

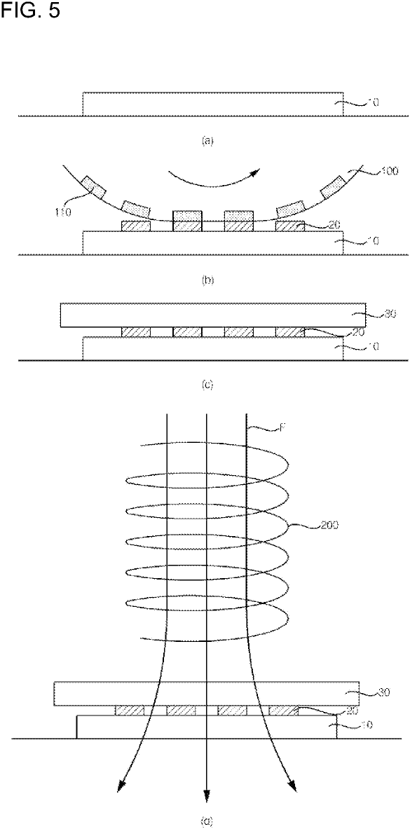

Hereinafter, the generation of the conductive film 20 using the conductive paste as shown in FIG. 1 will be described in detail with reference to FIGS. 4 and 5.

FIG. 4 is a flowchart illustrating a method of forming the conductive film 20 substrate (1) of FIG. 1, and FIGS. 5A to 5D are process diagrams illustrating the process of FIG. 4.

Referring to FIG. 4, the substrate 10 is provided as shown in FIG. 5A (S100).

The substrate 10 may be mainly a printed circuit board 10, and may be a flexible substrate 10 or a rigid substrate 10. As a material of the substrate 10, various materials such as metal, organic, and inorganic materials may be used. The substrate 10 may be a wiring board 10, a heat sink, or the like. In the case of the heat sink, it may be a metal plate.

In this connection, a conductive paste used as a solder is applied to a predetermined position over the substrate 10 (S110).

Such application of the conductive paste may be performed by applying the conductive paste accommodated in a groove 110 of a roll 100 to the corresponding position in a roll-to-roll method, or by printing as shown in FIG. 5B, without being limited thereto.

The printing method may be performed by any one of screen printing, ink jet, gravure, flexo, offset, and aerosol.

When the conductive paste is applied in a specific shape over the substrate 10 in this way, it is disposed so as to be in contact with a bonding terminal of a device 30 to be bonded as shown in FIG. 5C.

In this connection, the device 30 to be bonded may be various electronic components or may be a part of another printed circuit board 10.

Next, induction heating is performed as shown in FIG. 5D (S120).

Induction heating may be implemented by an inductor oven, and a line of magnetic force passing through a corresponding conductive film is generated by flowing a predetermined high-frequency current to a coil of the inductor oven. In this connection, the high frequency may use a frequency of 1 kHz to 40 MHz, preferably 1 kHz to 10 MHz, more preferably 100 kHz to 5 MHz, and most preferably 200 kHz to 2 MHz.

In this connection, after primary sintering of the metal particles 21 by the self-heating (Hysteresis Loss) of the magnetic heating element 23 in the conductive film by the line of magnetic force, the quasi-bulk metal particles 21 undergo secondary self-heating (Eddy Current Loss) and are sintered.

Accordingly, the secondary self-heating proceeds, the sintering speed is very fast, and thus the adhesion between the upper and lower substrates 10 is completed.

The following characteristics may be observed for the adhesive conductive film 20 formed in this way.

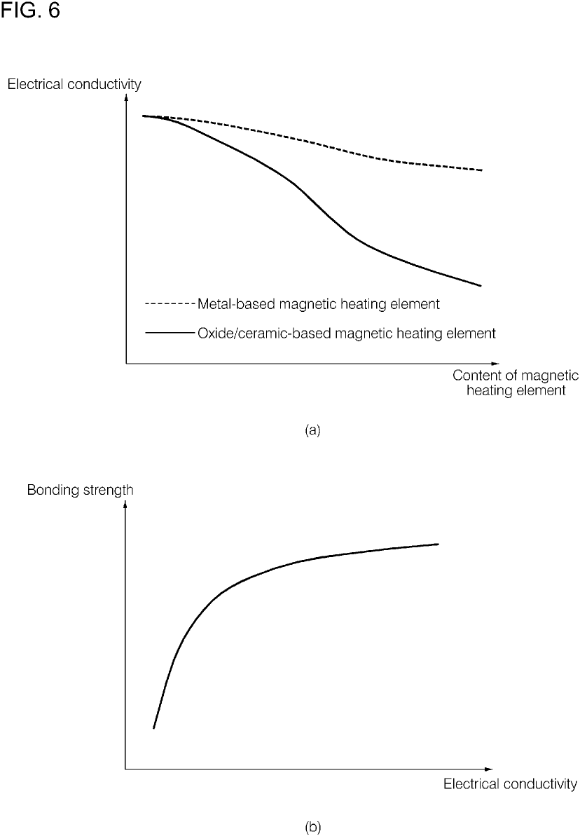

FIG. 6 is a graph illustrating the relationship between electrical conductivity with respect to the content of the magnetic heating element 23 according to the device and a graph illustrating the relationship between electrical conductivity and bonding strength.

Referring to FIG. 6A, for the different magnetic heating elements 23, electrical conductivity according to the content of the heating elements 23 was observed.

According to this, when the content of the magnetic heating element 23 with respect to the conductive particles increases, the electrical conductivity tends to decrease regardless of a material.

In this connection, the decrease in the oxide/ceramic-based magnetic heating element 23 with low electrical conductivity is larger than that of the metal-based magnetic heating element, which means that as the content of the metal-based magnetic heating element 23 increases, during induction heating bonding, the magnetic heating element 23 is exposed to the air and the surface of the magnetic heating element 23 is oxidized. Hence, it is interpreted as a decrease in electrical conductivity.

Referring to FIG. 6B, in the case of the adhesive conductive film 20, it may be seen that the higher the bonding strength, the less defects (residual organic material 22/pores) therein are relatively few, so that the electrical conductivity is excellent.

With respect to the formation of the conductive film 20 of FIG. 1, the maximum reaching temperature and heat-up time by the frequency of the same magnitude were measured while changing the content and material of the magnetic heating element 23.

In this connection, the metal particles 21 in each experiment were variously selected as silver (Ag), and the magnetic heating element 23 was variously selected. Only iron oxide (FesO₄) was measured while changing the content.

The results are shown in Table 1 below.

TABLE 1

| Experiment | Heating technology | | | | | Weight % | Reaching temperature | Heat-up time (seconds) |
|---|---|---|---|---|---|---|---|---|
| | | Type | Content | Type | Content | | | |
| 1 | Oven heating | Ag | 100 g | Fe₃O₄ | 0 g | 0 | 200° C. | 3 minutes (No significant difference) |
| 2 | | | | | 5 g | 5 | | |
| 3 | | | | | 10 g | 10 | | |
| 4 | | | | | 50 g | 50 | | |
| 5 | Induction heating | | | | 0 g | 0 | 40° C. | 300 seconds ↑ |
| 6 | | | | | 5 g | 5 | 200° C. | 60 seconds |
| 7 | | | | | 10 g | 10 | 200° C. | 20 seconds |
| 8 | | | | | 20 g | 20 | 200° C. | 5 seconds |
| 9 | | | | | 50 g | 50 | 200° C. | 2 seconds ↓ |
| 10 | | | | NiFe₂O₄ | 10 g | 10 | 200° C. | 200 seconds |
| 11 | | | | MnFe₂O₄ | 10 g | 10 | 200° C. | 15 seconds |
| 12 | | | | (MnZn)₁Fe₂O₄ | 10 g | 10 | 200° C. | 35 seconds |
| 13 | | | | Fe_{2.6}Co_{0.2}Mn_{0.2} | 10 g | 10 | 200° C. | 80 seconds |
| 14 | | | | Fe_{2.4}Co_{0.6} | 10 g | 10 | 200° C. | 54 seconds |
| 15 | | | | Fe₂Ni₁ | 10 g | 10 | 200° C. | 56 seconds |
| 16 | | | | Sm₂Co₇ | 50 g | 10 | 40° C. | 300 seconds ↑ |

Weight% (parts per hundred) indicates the mass of the magnetic heating element 23 with respect to 100 g of the metal particles 21. Table 1 shows the correlation between the time to reach 200° C. and the content of the magnetic heating element 23 during induction heating after 1 to 50 wt% of the magnetic heating element 23 is added.

Specifically, by analyzing Table 1, when the heat-up time for each content increase of Fe₃O₄ is analyzed, it may be observed that as the content of the magnetic heating element 23 increases, it rapidly reaches 200° C. during induction heating. In addition, it may be observed that a longer time is required for induction heating to reach 200° C. during oven heating, so that induction heating is more efficient.

In this connection, when taking a look at Experiment No. 5, it is observed that the temperature does not increase even when the metal particles 21 alone performs induction heating for a long time.

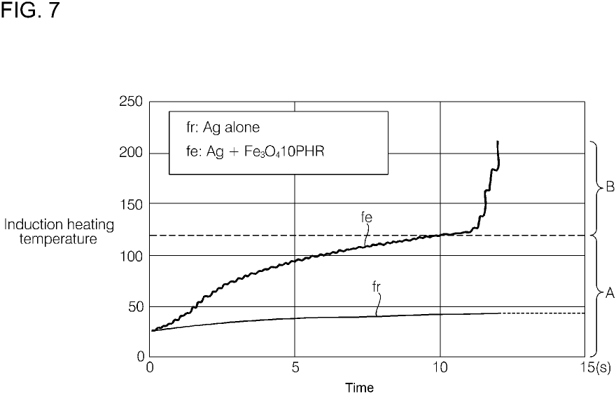

FIG. 7 is a graph illustrating the induction heating temperature according to time for each material.

Referring to FIG. 7, as shown in Table 1, when the metal particles 21 alone perform induction heating (fr graph), sintering proceeds only with the first rise without an additional increase in temperature even after a time elapses, and the temperature at which sintering proceeds is also observed to be very low (section A).

In this connection, when 10 wt% of iron oxide is added to the metal particles 21 (fe graph), a secondary rise (section B) is observed, and it may be seen that the temperature is raised to a very high temperature of 200° C. or higher within 20 seconds.

In addition, each electrical conductivity was measured for a similar experiment.

The results are shown in Table 2.

TABLE 2

| Experiment | Heating technology | Metal particles (21) | | Heating element (23) | | Wight % | Conductive film |
|---|---|---|---|---|---|---|---|
| | | Type | Content | Type | Content | | Electrical conductivity (%) |
| 1 | Oven heating | Ag | 100 g | Fe₃O₄ | 0 g | 0 | 100% |
| 2 | | | | | 5 g | 5 | 95% |
| 3 | | | | | 10 g | 10 | 80% |
| 4 | | | | | 50 g | 50 | 70% |
| 5 | Induction heating | | | | 0 g | 0 | N/A |
| 6 | | | | | 5 g | 5 | 100% |
| 7 | | | | | 10 g | 10 | 95% |
| 8 | | | | | 20 g | 20 | 85% |
| 9 | | | | | 50 g | 50 | 75% |
| 10 | | | | NiFe₂O₄ | 10 g | 10 | 92% |
| 11 | | | | MnFe₂O₄ | 10 g | 10 | 93% |
| 12 | | | | (MnZn)₁Fe₂O₄ | 10 g | 10 | 90% |
| 13 | | | | Fe_{2.6}Co₀.₂Mn_{0.2} | 10 g | 10 | 97% |
| 14 | | | | Fe_{2.4}Co_{0.6} | 10 g | 10 | 98% |
| 15 | | | | Fe₂Ni₁ | 10 g | 10 | 98% |
| 16 | | | | Sm₂Co₇ | 50 g | 50 | N/A |

In the case of Table 2, the experimental method is the same as in Table 1, and electrical conductivity was additionally measured. Upon analyzing Table 2, it may be seen that as the content of the magnetic heating element 23 (Fe₃O₄) increases, the electrical conductivity of the conductive film decreases. It may be observed that when the content of the magnetic heating element 23 is 5 wt% during induction heating, it has electrical conductivity similar to oven heating without the magnetic heating element 23. Similar to oven heating, it is observed that the electrical conductivity of the conductive film decreases as the content of the magnetic heating element 23 increases even during induction heating.

As such, as a result of simultaneous analysis of Tables 1 and 2, when the magnetic heating element is contained in a predetermined range, in other words, 10 to 20 wt% with respect to the Fe₃O₄ metal particle Ag, the temperature is raised to 200 degrees by induction heating within 20 seconds. Thereby, the desired effect may be obtained by securing the electrical conductivity to 85% or more.

In this connection, since the residual organic material 22 is relatively small, the electrical conductivity is higher during induction heating compared to oven heating, which is interpreted that the sintering density of the conductive film is improved by induction heating.

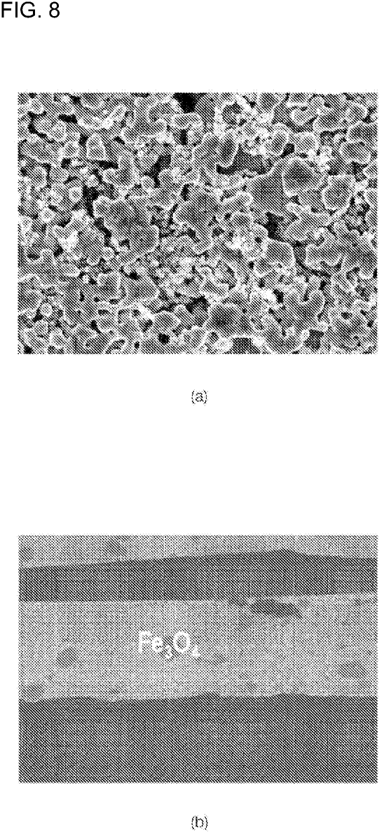

FIGS. 8A and 8B show a surface photograph and a tomographic photograph of the conductive film 20 produced according to an embodiment of the present invention, respectively.

FIG. 8A shows the surface of the conductive film 20 obtained by induction heating of the conductive film containing nano-sized Ag metal particles 21 and 10 wt% of Fe₃O₄ at 200 degrees for 20 seconds, and FIG. 8B is an analysis of its cross section.

As shown in FIG. 8A, it is observed that the surface is melted so that the particle size may not be measured. As shown in FIG. 8B, it may be seen that a very thin film with a thickness of about 187 µm of an Ag sintered body may be formed.

Hereinbefore, although preferred embodiments of the present invention have been illustrated and described, the present invention is not limited to the specific embodiments described above, and it goes without saying that persons having ordinary skills in the technical field to which the present invention pertains may implement the present invention by various modifications thereof without departing from gist of the present invention defined by the claims, and such modifications are within the scope of the claims.

Description of Reference Numerals

| | |
|---|---|
| 10: Substrate | 20: Conductive film |
| 21: Metal particles | 23: Magnetic heating element |

What is claimed is:

1. A conductive paste including:
an organic material including an organic solvent and a dispersant;
metal particles dispersed in the organic material and having a first particle diameter; and
a magnetic heating element dispersed in the organic material and having a second particle diameter,
wherein the magnetic heating element is contained in an amount of 10 to 50 wt% with respect to the metal particles.

2. The conductive paste of claim 1, wherein the second particle diameter of the magnetic heating element is the same as or smaller than the first particle diameter of the metal particles.

3. The conductive paste of claim 1, wherein the magnetic heating element is mixed in an amount of 10 to 20 wt% with respect to the metal particles.

4. The conductive paste of claim 1, wherein the magnetic heating element is a metal oxide-based magnetic heating element.

5. The conductive paste of claim 4, wherein the magnetic heating element is a Fe₃O₄ magnetic heating element.

6. The conductive paste of claim 1, wherein the metal particles are at least one of Ag, Ag, Al, Pt, Sn, Cu, Zn, Pd, and Ni.

7. The conductive paste of claim 1, wherein the first particle diameter is 10 nm to 100 um.

8. The conductive paste of claim 7, wherein the first particle diameter is 10 nm to 50 um.

9. The conductive paste of claim 1, wherein the second particle diameter is 10 nm to 10 um.

10. The conductive paste of claim 1, wherein the dispersant or organic solvent of the organic material has 30 or less carbon atoms.

11. The conductive paste of claim 1, wherein the organic material further includes a binder and a catalyst.

12. The conductive paste of claim 1, wherein the thickness of the conductive paste is 0.001 mm to 0.5 mm.

13. A method of producing a conductive paste, the method including:
mixing and dispersing an organic material and metal particles having a first particle diameter;
dispersing a magnetic heating element having a second particle diameter of 10 to 50 wt% with respect to the metal particles in the organic material in which the metal particles are dispersed; and
post-processing and subdividing the organic material in which the metal particles and the magnetic heating element are mixed.

14. The method of claim 13, wherein the second particle diameter of the magnetic heating element is the same as or smaller than the first particle diameter of the metal particles.

15. The method of claim 13, wherein the magnetic heating element is mixed in an amount of 10 to 20 wt% with respect to the metal particles.

16. A method of producing a conductive film, the method including:
applying, on a substrate, a conductive paste including metal particles that are dispersed in an organic material and have a first particle diameter, and a magnetic heating element that has a second particle diameter; and
selectively sintering the applied conductive paste by induction heating to form a conductive film,
wherein the magnetic heating element is contained in an amount of 10-50 wt% with respect to the metal particles.

17. The method of claim 16, wherein in the induction heating, the conductive paste is sintered through a magnetic field generated by a high frequency ranging from 1 kHz to 40 MHz.

18. The method of claim 16, wherein in the induction heating, the temperature is raised to 200° C. or higher within 20 seconds.

19. The method of claim 16, wherein in the applying, on the substrate, of the conductive paste, the conductive paste is applied over the substrate by a roll-to-roll method or a printing method.

20. The method of claim 16, further including disposing an adhesive object over the conductive paste after applying the conductive paste on the substrate.
